(19) United States
(12) Patent Application Publication
(10) Pub. No.: US 2002/0007794 A1
(43) Pub. Date: Jan. 24, 2002

(54) Plasma processing apparatus

(76) Inventors: Hong-Sik Byun, Songnam-shi (KR); Gi-Chung Kwon, Kwangju-gun (KR); Sung-Weon Lee, Yongin-shi (KR); Hong-Seub Kim, Yongin-shi (KR); Sun-Seok Han, Suwon-Shi (KR); Yong-Kwan Lee, Taejon (KR); Dong-Seok Lee, Pusan (KR); Hong-Yong Chang, Taejon (KR)

Correspondence Address: Timothy J. Keefer, Wildman, Harrold, Allen & Dixon, 225 West Wacker Drive, Chicago, IL, 60606, US

(21) Appl. No.: 09/871,431

(22) Filed: May 31, 2001

(30) Foreign Application Priority Data
Jun. 1, 2000 (KR) 2000-30050

(51) Int. Cl. H01L 21/3065

(52) U.S. Cl. 118/723 I; 156/345

(57) ABSTRACT

Disclosed is an inductively coupled plasma processing apparatus which has a very-high-frequency parallel antenna producing inductively-coupled plasma for a large substrate. This plasma processing apparatus includes a very high frequency power source in order to generate the high dense plasma, and parallel-connected antenna units that receive the very high frequency power from the very high frequency source. The very high frequency power has a frequency of 20 MHz to 300 MHz. According to present invention, while the plasma density can be raised, the electron temperature can be lowered. Thus, when the dry etch process is conducted using CFₓ, the CFₓ/F ratio can be adjusted to have the low density of fluorine radical. And also, it is possible to have the high radical density of CF₂, CF₃ and the like. As a result, the proper radical ratio, which is relative to increase selection ratio, enhances the dry etch process excellently.

This application claims the benefit of Korean Patent Application No. 2000-30050, filed on Jun. 1, 2000, which is hereby incorporated by reference.

### BACKGROUND OF THE INVENTION

1. Field of the Invention

This invention relates to a plasma processing. More particularly, it relates to a plasma processing apparatus which has a very-high-frequency parallel antenna producing inductively-coupled plasma for treating a large substrate.

2. Discussion of the Related Art

In a field of manufacturing a semiconductor wafer and a flat panel display, the surface treatment processes such as a dry etching, a chemical vapor deposition and a sputtering use plasma. Recently, in order to achieve lower cost and higher throughput, the semiconductor wafer and the flat panel display tend to be larger in size. The semiconductor wafer particularly tends to have a diameter of greater than 300 mm. As a result, the plasma processing apparatus is changing so as to be suitable for new and different wafer and display panel.

A method of generating the plasma is classified into the diode type, the microwave type and the radio frequency wave type, all of which use a high frequency power. However, they have some problems and limitations.

In accordance with the diode type, minute patterns cannot be achieved during patterning process, because the diode type apparatus has difficulty in controlling a high voltage and needs high-pressure gases.

In accordance with ECR (electron cyclotron resonance) type that is a sort of the microwave type, the plasma density increases even under lower pressure of the gases. However, the uniformity of the plasma density is hardly obtained in a chamber, and this phenomenon become greater whenever the quantity of the plasma is raised.

In accordance with helicon wave type that is relatively a sort of the radio frequency (RF) wave type, often referred to as an inductively coupled plasma type, when generating the small quantity of the plasma, the uniformity of the plasma having a high density can be obtained by way of mutual reactions of the electric field and the magnetic field and by way of exciting the gaseous medium within the chamber. However, when generating the large quantity of the plasma, this helicon type apparatus also has the problem that the density distribution is not uniform. Further, since the conventional plasma processing apparatus uses a radio frequency (RF) electric power, this apparatus has a limitation of lowering an electron temperature of the plasma.

Hereinafter, reference will be made in detail to the conventional inductively coupled plasma processing apparatus, which is illustrated in the accompanying drawings.

FIG. 1 is a schematic diagram illustrating the conventional inductively coupled plasma processing apparatus. As shown, the plasma processing apparatus 10 is widely comprised of a vacuum vessel portion and a high frequency power source portion. The vacuum vessel portion includes a vacuum chamber 11 generating the plasma 12 therein, a gas pipe 8 supplying a process gas, a vacuum pump 20 exhausting residual gases in the vacuum chamber 11, and an exhaust pipe 18. The gas pipe 8 is formed in the upper portion of the vacuum chamber 11 and the exhaust pipe 18 is formed in the lower portion of the vacuum chamber 11. The vacuum pump 20 communicates with the vacuum chamber 11 via the exhaust pipe 18.

Further, a chuck 14 is usually arranged in the interior bottom of the vacuum chamber 11 and acts as a means for mounting a wafer or substrate 16. On the top of the vacuum chamber 11, an insulating plate 6 is arranged in order to place an antenna 4 thereon. Since the insulating plate 6 decreases capacitive coupling between the antenna 4 and the plasma 12 formed in the vacuum chamber 11, the insulation plate 6 helps the high frequency power to be transferred to the plasma 12 by way of inductive coupling.

Moreover, the high frequency power source portion includes a first high frequency power source 2 that is connected to the antenna 4, and a second high frequency power source 22 that is connected to the chuck 14. The first and second high frequency power sources 2 and 22 supply a radio frequency (RF) power having a frequency of less than 20 MHz to the antenna 4 and the chuck 14, respectively.

It will be described how the plasma processing apparatus 10 generates the plasma.

At first, the vacuum chamber 11 is vacuumized by the vacuum pump 20. Next, a process gas for the plasma is supplied into the vacuum chamber 11 through the gas pipe 8, and a predetermined pressure is maintained. The first high frequency power source 2 then supplies the radio frequency (RF) power having a frequency of 13.56 MHz to the antenna 4. At this time, a changing magnetic field, which is changeable relatively to the time in a direction perpendicular to the plane of the antenna 4, is generated depending on the supplied RF power. The changing magnetic field induces an electric field under the antenna 4. The induced electric field is substantially concentric and runs in a circumferential direction. What should be noted is that electrons are accelerated in the circumferential direction by the electric field and collide against the neutral particles within the process gas so as to ionize the gaseous molecules, and thus, to form a plasma such as ion or radical. Meanwhile, the high frequency power applied to the chuck 14 by the second high frequency power source 22 controls the incident ion energy being projected to the wafer or substrate 16.

FIG. 2A is a schematic view showing the structure of an RF power applying apparatus for use in the inductively coupled plasma processing apparatus according to the conventional art. As shown, a coil antenna 4a is connected in series with an impedance matching box (I.M.B) 3a, and then the impedance matching box (I.M.B) 3a is connected to the high frequency power source 2a. In this structure, since each winding (for example, a-b, b-c, c-d or c-e) of the series-connected coil antenna 4a is connected in series with other windings of that antenna 4a, the intensity of an electric current uniformly flows through the series-connected coil antenna 4a. In the case of this conventional structure, however, it is difficult to control the induced electric field distribution. And the plasma density becomes high in the center of the vacuum chamber, while the plasma density declines near an inner wall of the vacuum chamber. That is because of the ion and/or the electron loss in the inner wall of the vacuum chamber.

Therefore, it is very difficult to maintain the plasma density uniformly in the vacuum chamber. Furthermore, since the windings (for example, a-b, b-c, c-d and d-e of FIG. 2A) are connected in series with each other, a related problem is that a voltage drop is raised by the series-connected coil antenna 4a, thereby increasing the effect of the conductive coupling to the plasma. Accordingly, the power consumption increases and the plasma uniformity is difficult to be maintained.

FIG. 2B is a view showing an equivalent circuit of FIG. 2A. As shown, the high frequency power from the high frequency power source 2a is supplied to each impedance Z₁, Z₂, Z₃ or Z₄. Due to the series connection of the windings (i.e., a-b, b-c, c-d and d-e) of the coil antenna 4a, the impedance is greater in the series connection than in the parallel connection. Therefore, the insulating plate 6 of FIG. 1 arranged between the antenna 4 and the vacuum chamber 11 is damaged by the plasma.

FIG. 3 is a schematic view showing the structure of an RF power applying apparatus for use in the inductively coupled plasma processing apparatus according to another conventional art. As shown, this apparatus includes first, second and third high frequency power sources 2b, 2c and 2d. This RF power supplying apparatus also has first, second and third divided antennas 4b, 4c and 4d that form a loop shape. The first high frequency power source 2b is connected with the first antenna division 4b through a first impedance matching box 3b; the second high frequency power source 2c is connected with the second antenna division 4c through a second impedance matching box 3c; and the third high frequency power source 2d is connected with the third antenna division 4d through a third impedance matching box 3d.

The plasma processing apparatus of the antenna division type depicted in FIG. 3 has a technical problem, i.e., the plasma is difficult to be uniformly generated. Namely, the plasma density is high near each antenna division 4b, 4c and 4d, but is low in the central core portion of the vacuum chamber 11 of FIG. 1. Thus, the plasma uniformity is difficult to be achieved. Owing to this problem, it is can hardly be used for the large substrate. Further, since this type of apparatus needs an individual power source to each antenna division, the cost becomes higher and the individual impedance matching box is required for efficient use of the power and for impedance matching.

As described above, since the conventional inductively coupled plasma processing apparatus has the series-connected coil antenna that has the high impedance value, the high frequency power source having a frequency of greater than 20 MHz can not be used.

### SUMMARY OF THE INVENTION

Accordingly, the present invention is directed to an inductively coupled plasma processing apparatus that substantially obviates one or more of the problems due to limitations and disadvantages of the related art.

To overcome the problems described above, the present invention provides a plasma processing apparatus that treats the large-sized substrate using a uniform density of the plasma.

Another object of the invention is to provide a plasma processing apparatus that can adjust the radical ration in order to decrease the electron temperature of the plasma and to increase the processing selection ratio.

Another object of the present invention is to provide a plasma processing apparatus that can be used in a plasma dry etch process by way of having a large etch selectivity to a layer on the substrate.

Additional features and advantages of the invention will be set forth in the description which follows, and in part will be apparent from the description, or may be learned by practice of the invention. The objectives and other advantages of the invention will be realized and attained by the structure particularly pointed out in the written description and claims thereof as well as the appended drawings.

To achieve these and other objects and in accordance with the purpose of the present invention, as embodied and broadly described a plasma processing apparatus having a vacuum chamber for generating plenty of inductively coupled plasmas therein, including: a first very high frequency power source that supplies a very high frequency power having a frequency of 20 to 300 MHz; and a plurality of antenna units parallel-connected each other and applied the very high frequency power by the first very high frequency power source, the antenna units comprising a antenna; wherein the vacuum chamber has a reaction space where the inductively coupled plasmas are generated by the antenna units.

One of the antenna units has at least one variable load that is connected in series. The antenna units having at least one variable load is located in outer part of the antenna. The variable load is a variable capacitor.

A plasma processing apparatus further comprises an impedance matching box that is respectively connected to the very high frequency power source and the antenna. The parallel-connected antenna units maintain a resonance state each other. A plasma processing apparatus further comprises a chuck in the vacuum chamber for mounting a substrate thereon. A plasma processing apparatus further comprises a second very high frequency power source that supplies a very high frequency power having a frequency of 20 to 300 MHz to the chuck.

The preferred embodiment of the present invention further provides a radio frequency (RF) power supplying apparatus, including: a very high frequency power source supplying a very high frequency power having a frequency of 20 to 300 MHz; an impedance matching box connected to the very high frequency power source; and a plurality of antenna units connected in parallel each other; wherein a plurality of the antenna units comprise a antenna; and wherein each antenna unit has at least one variable capacitor and a coil antenna.

It is to be understood that both the foregoing general description and the following detailed description are exemplary and explanatory and are intended to provide further explanation of the invention as claimed.

### BRIEF DESCRIPTION OF THE DRAWING

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic diagram illustrating a conventional inductively coupled plasma processing apparatus;

FIG. 2A is a schematic view showing the structure of an RF power applying apparatus used in an inductively coupled plasma processing apparatus according to a conventional art;

FIG. 2B is a view showing an equivalent circuit of FIG. 2A;

FIG. 3 is a schematic view showing the structure of an RF power applying apparatus for use in the inductively coupled plasma processing apparatus according to another conventional art;

FIG. 4 is a schematic diagram illustrating an inductively coupled plasma processing apparatus according to the present invention;

FIG. 5A is a schematic view showing the structure of an RF power applying apparatus for use in the inductively coupled plasma processing apparatus of FIG. 4 according to a first embodiment of the present invention;

FIG. 5B is a view showing an equivalent circuit of FIG. 5A;

FIG. 6A is a schematic view showing the structure of an RF power applying apparatus used in the inductively coupled plasma processing apparatus of FIG. 4 according to a second embodiment of the present invention;

FIG. 6B is a view showing an equivalent circuit of FIG. 6A;

FIG. 7 is a graph showing a relationship between frequency and electron temperature;

FIG. 8A is a graph showing radical characteristics when a radio frequency power having frequency of 13.56 MHz and power of 2 kW is supplied to an antenna of a conventional inductively coupled plasma processing apparatus;

FIG. 8B is a graph showing radical characteristics when a very high frequency power having frequency of 100 MHz and power of 2 kW is supplied to an antenna of the inductively coupled plasma processing apparatus according to the present invention; and

FIG. 9 is a schematic view showing the structure of an RF power applying apparatus for use in the inductively coupled plasma processing apparatus of FIG. 4 according to a third embodiment of the present invention.

### DETAILED DESCRIPTION OF THE PREFERRED EMBODIMENTS

Reference will now be made in detail to embodiments of the present invention, which are illustrated in the accompanying drawings. Wherever possible, the same reference numbers will be used throughout the drawings to refer to the same or like parts.

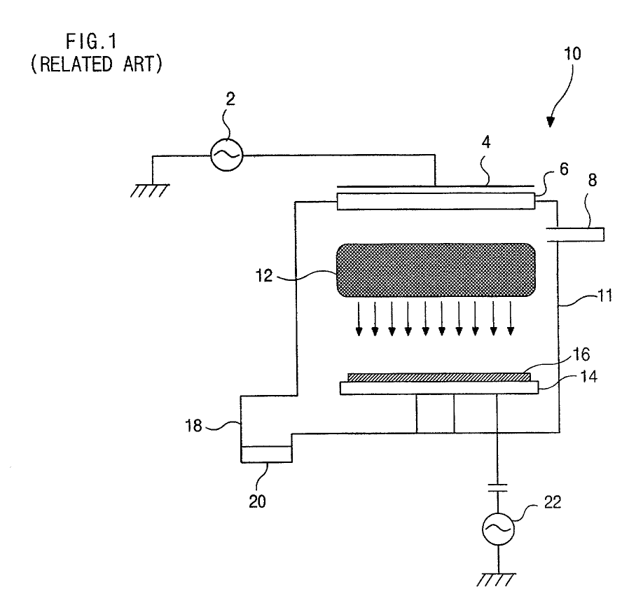

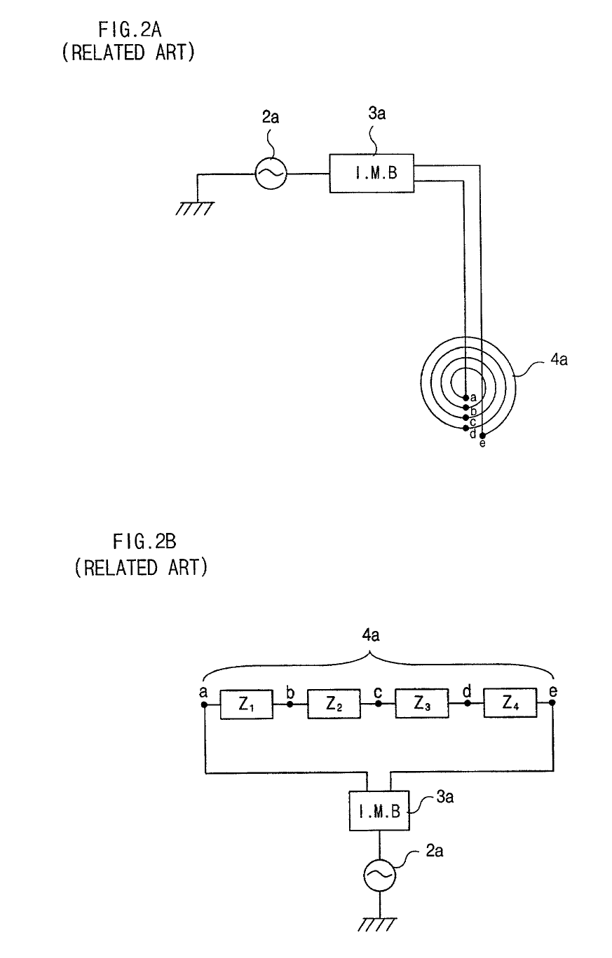

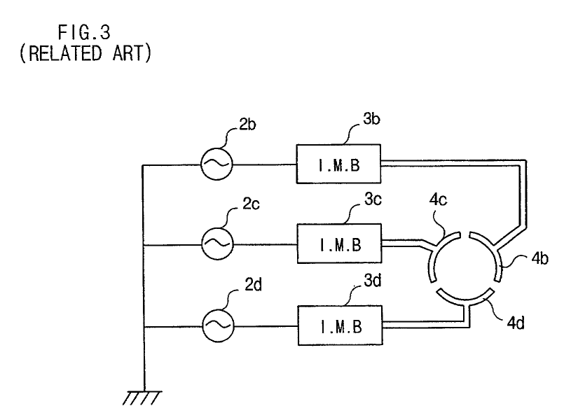

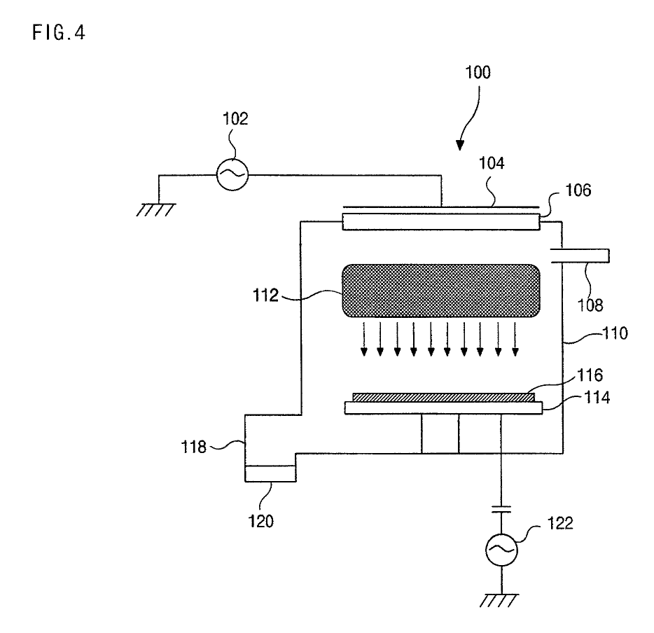

FIG. 4 is a schematic diagram illustrating an inductively coupled plasma processing apparatus according to the present invention. Although FIG. 4 is similar to FIG. 1, the RF power supplying apparatus has different structure from the conventional art depicted in FIG. 1.

As shown in FIG. 4, the plasma processing apparatus 100 is widely comprised of a vacuum vessel portion and a very high frequency power source portion. The vacuum vessel portion includes a vacuum chamber 110 generating the plasma 112 therein, a gas pipe 108 supplying a process gas, a vacuum pump 120 exhausting residual gases in the vacuum chamber 110, and an exhaust pipe 118. The gas pipe 108 is formed in the upper portion of the vacuum chamber 110 and the exhaust pipe 118 is formed in the lower portion of the vacuum chamber 110. The vacuum pump 120 communicates with the vacuum chamber 110 via the exhaust pipe 118.

Further, a chuck 114 is arranged in the interior bottom of the vacuum chamber 110 and acts as a means for mounting a wafer or substrate 116. On the top of the vacuum chamber 110, an insulating plate 106 is arranged in order to place an antenna 104 thereon. Since the insulating plate 106 decreases capacitive coupling between the antenna 104 and the plasma 112 formed in the vacuum chamber 110, the insulation plate 106 helps the very high frequency power to be transferred to the plasma 112 by way of inductive coupling.

Moreover, the very high frequency power source portion includes a first very high frequency power source 102 that is connected to the antenna 104, and a second very high frequency power source 122 that is connected to the chuck 114. The first and second very high frequency power sources 102 and 122 supply a radio frequency (RF) power having a frequency of 20 to 300 MHz to the antenna 104 and chuck 114, respectively. The advantage of the very high frequency will be explained later, and the explanation of the system of generating the plasma is omitted because it is the same as the conventional art described before.

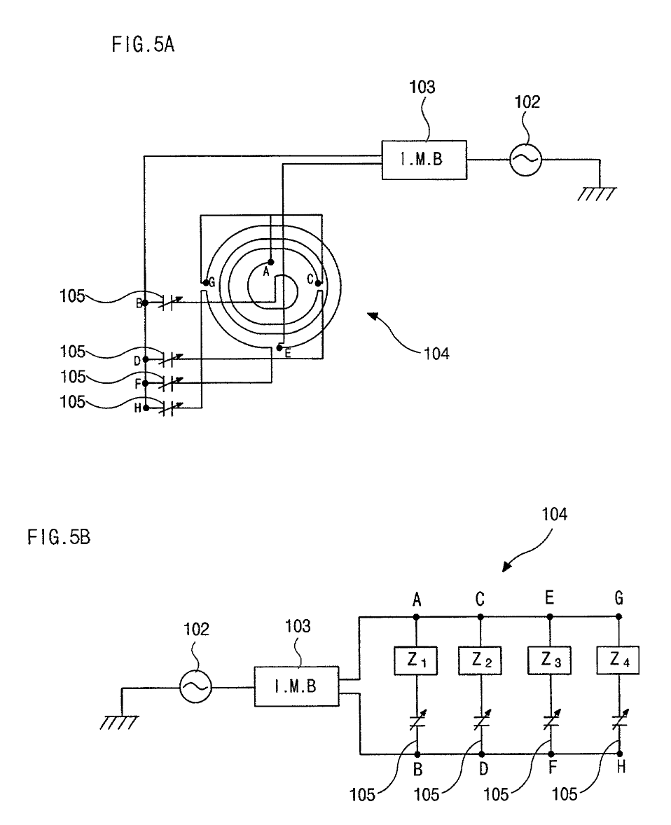

FIG. 5A is a schematic view showing the structure of an RF power applying apparatus for use in the inductively coupled plasma processing apparatus of FIG. 4 according to a first embodiment of the present invention. As shown, the antenna 114 is comprised of first, second, third and fourth antenna units that are connected in parallel. The first antenna unit includes a coil antenna A-B with a series-connected variable load; the second antenna unit includes a coil antenna C-D with a series-connected variable load; the third antenna unit includes a coil antenna E-F with a series-connected variable load; and the fourth antenna unit includes a coil antenna G-H with a series-connected variable load. Here in FIG. 5, the variable load is indicated as a variable capacitor 105. An impedance matching box 103 is located between the first very high frequency power source 102 and each antenna unit. The variable load of each antenna unit is, for example, a variable capacitor 105 that maintains a resonance state between the antenna units. The number of the antenna units is changeable depending on the desirable property of the plasma processing apparatus.

FIG. 5B is a view showing an equivalent circuit of FIG. 5A. As shown, the winding of the coil antenna of each antenna unit can be comprised of the single or double winding of wire, and the winding of the coil antenna can be represented by the impedance Z₁, Z₂, Z₃ or Z₄ that includes equivalent resistance and equivalent inductance. If the variable capacitors 105 are adjusted to make the imaginary portion of the equivalent impedance of each antenna unit be zero, the resonance state is maintained. Thus, the resonance state results in the equivalent intensity of the electric current flowing each antenna unit, by way of adjusting the variable capacitors 105. Then, the electric current flowing the antenna units can increase from the above-mentioned process.

Namely, the capacity of the variable capacitor 105 is firstly determined in order to control the energy transmitted to the antenna 104. Next, the capacity of the capacitor 105 is adjusted in order to maintain the resonance state between the coil antennas. And then, by way of matching the impedance of the antenna 104 to the very high frequency power source 102, the radio-frequency energy applied from the very high frequency power source 102 is easily transmitted to the plasma in the vacuum chamber. Moreover, the plasma uniformity increases in view of matching the impedance. According to the principles of the present invention, the number of the antenna unit is changeable even if the antenna 104 maintains the resonance state. Since each antenna unit includes the variable load, the current ratio flowing the two antenna units is controlled by way of controlling the variable loads arranged in the two antenna units. Further, the other antenna units are used for inducing the resonance state in the circuit. According to the present invention, the antenna units having the resonance states are arranged in and used for the outer parts of the antenna 104, and the other antenna units are arranged in and used for the inner parts of the antenna 104. Therefore, the energy uniformity is readily achieved in all over the antenna 104.

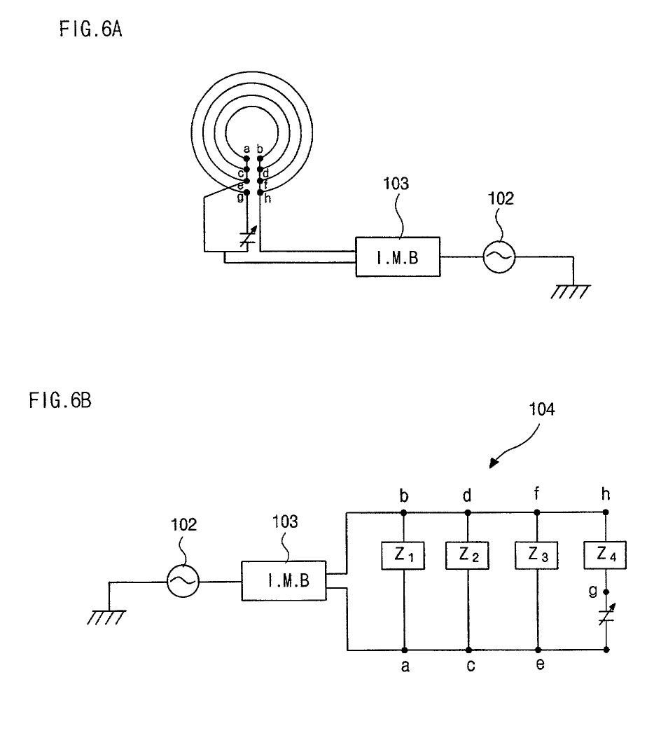

FIG. 6A is a schematic view showing the structure of an RF power applying apparatus for use in the inductively coupled plasma processing apparatus of FIG. 4 according to a second embodiment of the present invention. And FIG. 6B is a view showing an equivalent circuit of FIG. 6A. As shown, although FIGS. 6A and 6B are respectively similar to the FIGS. 5A and 5B, the variable loads such as the variable capacitors can be omitted in the second embodiment.

According to the preferred embodiments of the present invention described above, since the plasma processing apparatus uses the very-high-frequency parallel antenna producing inductively coupled plasma, the problem of matching the impedance does not occur although the frequency of the applied power to the antenna is enhanced. Therefore, the very high frequency power having a frequency of 20 MHz to 300 MHz can be applied to the antenna, thereby generating the high dense plasma having low electron temperature. Namely, the electron temperature is controllable from 1.5 eV to 2.5 eV, and thus the process gas can be ionized in the optimum condition.

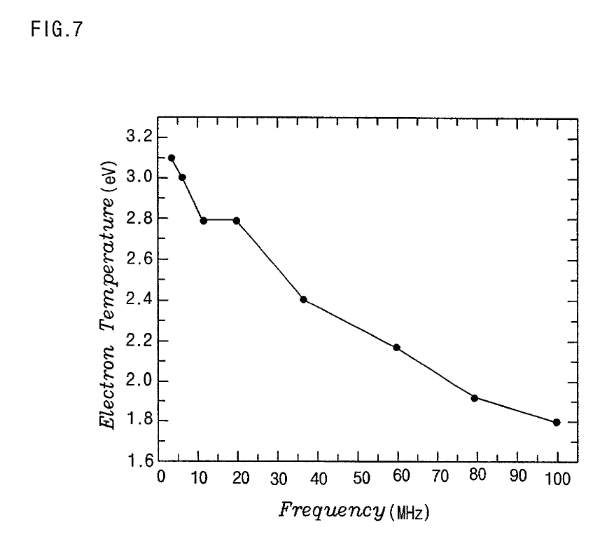

FIG. 7 is a graph showing a relationship between frequency and electron temperature. As shown, while the frequency of the applied power to the plasma becomes larger, the electron temperature of the plasma is getting lowered. Namely, the electron temperature (eV) is in inverse portion to the frequency (MHz). Therefore, since the plasma processing apparatus according to the present invention adopts the very-high-frequency parallel antenna producing inductively coupled plasma, to match impedance is easy although the applied power to the plasma has a frequency of 20 MHz to 300 MHz. Moreover, the very high frequency power is easily transmitted to the plasma, and thus the electron temperature is declined.

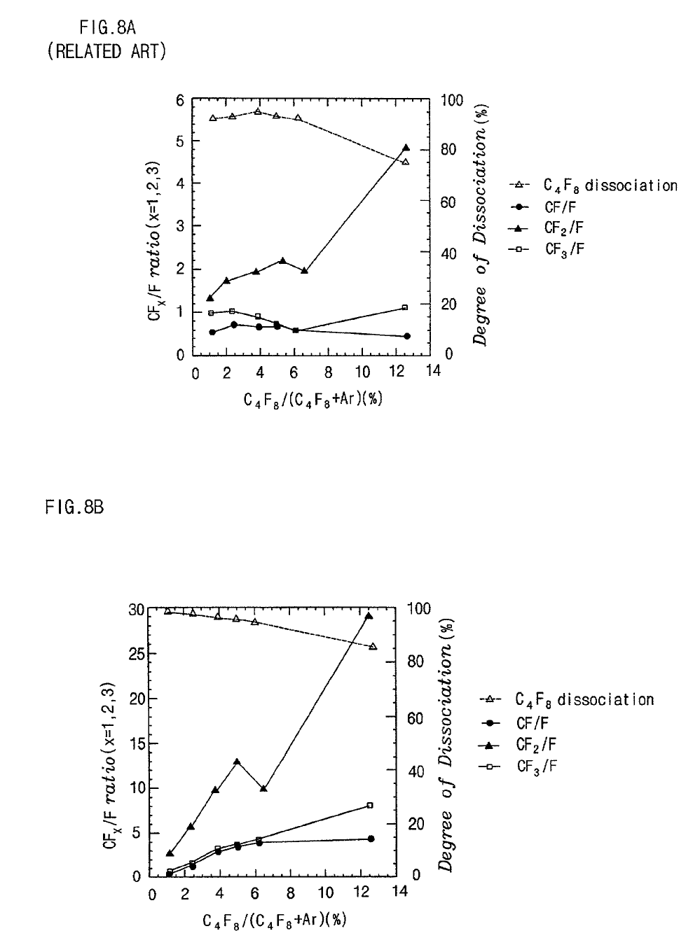

FIG. 8A is a graph showing radical characteristics when a radio frequency power having frequency of 13.56 MHz and power of 2 kW is supplied to an antenna of a conventional inductively coupled plasma processing apparatus. As shown, the degree of forming CFₓ radical is researched about the mixed gas of C₄F₈ and Ar while the pressure of the vacuum chamber is maintained at 2 mTorr. The research shows that the electron temperature of the plasma is about 3 eV.

FIG. 8B is a graph showing radical characteristics when a very high frequency power having frequency of 100 MHz and power of 2 kW is supplied to an antenna of the inductively coupled plasma processing apparatus according to the present invention. Compared to the graph of FIG. 8A, the electron temperature of the plasma is 2 eV when the pressure of the vacuum chamber is maintained at 2 mTorr.

Referring to the FIGS. 8A and 8B, the radical is plentifully generated when the very high frequency power having a frequency of 100 MHz is applied to the antenna, due to the low electron temperature of the plasma. Further, according to the embodiments, since the plasma processing apparatus has the very-high-frequency parallel antenna producing inductively coupled plasma, the CFₓ/F ratio can be adjusted to have the high radical density of CF₂, CF₃ and the like after the very high frequency power for generating the plasma is supplied. Further, the CFₓ/F ratio can also be adjusted to have the low density of fluorine radical after the very high frequency power for generating the plasma is supplied.

Further, according to the plasma processing apparatus having the very high frequency power for generating the inductively coupled plasma, when the parallel antenna is used for the antenna units, the resonance capacitor disposed in the outer parts of the antenna controls the intensity of the current flowing the antenna. Thus, the uniform plasma density can be achieved.

In other words, when the inductively coupled plasma processing apparatus uses the parallel-connected antenna, compared to the conventional series-connected antenna, the following advantages can be achieved.

First, since the impedance of the antenna is low, it is easy to match the impedance.

Second, since the high electric current flows the antenna, the high dense plasma can easily be achieved.

Third, since the voltage applied to the antenna is lower, the damage of the insulating plate caused by the capacitive electric field can be minimized.

Fourth, the radical is plentifully generated due to the low impedance applied to the parallel antenna and due to the easy impedance matching, although the very high frequency power is induced.

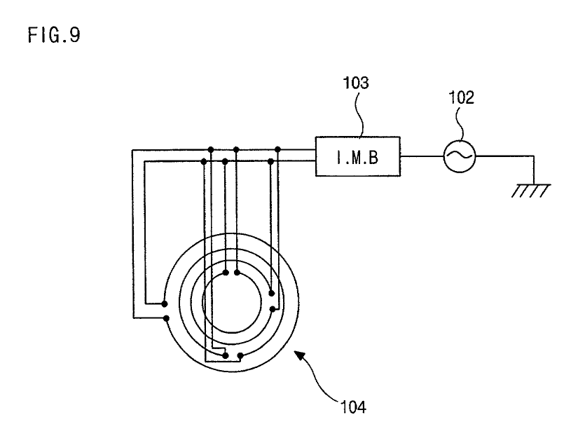

FIG. 9 is a schematic view showing the structure of an RF power applying apparatus for use in the inductively coupled plasma processing apparatus of FIG. 4 according to a third embodiment of the present invention. As shown, the antenna 104 is comprised of first, second, third and fourth antenna units that are connected in parallel. Namely, the antenna 104 includes these antenna units. FIG. 9 is similar to FIG. 5A, but each antenna unit does not include the variable capacitor. An impedance matching box 103 is located between the first very high frequency power source 102 and the antenna 104. The number of the antenna units is changeable depending on the desirable property of the plasma processing apparatus. In this embodiment, the very high frequency power from the first very high frequency power source 102 is applied to the parallel-connected antenna 104.

Moreover, the very high frequency power having a frequency of 20 MHz to 300 MHz can be applied to the chuck (see reference element 114 of FIG. 4). When this very high frequency power is applied to the chuck, the ion energy is readily controlled and then the process gas largely ionized. Thus, plenty of radicals are generated.

The aforementioned preferred embodiments are particularly useful when the plasma processing apparatus is used in a plasma dry etch process. This is due to the fact that the CFₓ/F ratio can be adjusted to have the low density of fluorine radical. And also, it is possible to have the high radical density of CF₂, CF₃ and the like when the dry etch process is conducted using CFₓ. Therefore, the proper radical ratio, which is relative to increase selection ratio, enhances the dry etch process excellently.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A plasma processing apparatus having a vacuum chamber for generating
plenty of inductively coupled plasmas therein, comprising:
a first very high frequency power source that supplies a very high frequency power having a frequency of 20 to 300 MHz; and
a plurality of antenna units being parallel-connected with each other and receiving the very high frequency power from the first very high frequency power source;
an antenna being comprised of the plurality of antenna unit;
wherein the vacuum chamber has a reaction space where the inductively coupled plasmas are generated by the plurality of antenna units.

2. An apparatus according to claim 1, wherein one of the antenna units has at least one variable load that is connected in series.

3. An apparatus according to claim 2, wherein the antenna units having at least one variable load is located in an outer part of the antenna.

4. An apparatus according to claim 3, wherein the variable load is a variable capacitor.

5. An apparatus according to claim 1, further comprising an impedance matching box that is connected to the very high frequency power source and the antenna.

6. An apparatus according to claim 5, wherein the parallel-connected antenna units maintain a resonance state therebetween.

7. An apparatus according to claim 6, further comprising a chuck in the vacuum chamber for mounting a substrate thereon.

8. An apparatus according to claim 7, further comprising a second very high frequency power source that supplies a very high frequency power having a frequency of 20 MHz to 300 MHz to the chuck.

9. An RF power supplying apparatus, comprising:
a very high frequency power source supplying a very high frequency power having a frequency of 20 MHz to 300 MHz;
an impedance matching box connected to the very high frequency power source;
a plurality of antenna units connected in parallel with each other; and
an antenna being comprised of the plurality of antenna units; and
wherein each antenna unit has at least one variable capacitor and a coil antenna.
